(19) United States
(12) Patent Application Publication
(10) Pub. No.: US 2018/0190406 A1
(43) Pub. Date: Jul. 5, 2018

(54) ELECTRIC WIRE STRUCTURE AND METHOD OF MANUFACTURING THEREOF

(71) Applicant: Haesung DS CO., Ltd., Changwon-si, Gyeongsangnam-do (KR)

(72) Inventors: Dong Kwan WON, Seoul (KR); Hyun Tae LIM, Seoul (KR); Jae Chul RYU, Seoul (KR)

(73) Assignee: Haesung DS CO., Ltd., Changwon-si, Gyeongsangnam-do (KR)

(21) Appl. No.: 15/545,962

(22) PCT Filed: Aug. 2, 2016
(86) PCT No.: PCT/KR2016/008495

§ 371 Date: Jul. 24, 2017

(30) Foreign Application Priority Data
May 24, 2016 (KR) 10-2016-0063295

(51) Int. Cl. H01B 1/02; H01B 13/00; C23C 16/26

(52) U.S. Cl. CPC H01B 1/02; C23C 16/26; H01B 13/0036

(57) ABSTRACT

Provided is an electric wire structure including a copper (Cu) electric wire extending in a direction; and a graphene coating layer formed on an outer portion of the Cu electric wire to surround the Cu electric wire, wherein the Cu electric wire includes Cu having a purity of 99.9% or greater.

### RELATED APPLICATIONS

This application claims priority benefit as a national phase of PCT/KR2016/008495, filed Aug. 2, 2016, and claims foreign priority benefit of KR 10-2016-0063295, filed May 24, 2016, all of which are incorporated herein by reference in their entirety.

### TECHNICAL FIELD

The present invention relates to an electric wire structure and a method of manufacturing the electric wire structure.

### BACKGROUND ART

Graphene is a material in which carbon atoms are connected to one another as hexagons to form a two-dimensional plane structure of a honeycomb shape, and is characterized in very small thickness, transparency, and an excellent electric conductivity. There have been many attempts to apply graphene to a touch panel, a transparent display, a flexible display, or the like by using the above characteristics of graphene.

Graphene is synthesized on a surface of a catalyst metal by a chemical vapor deposition (CVD) method after injecting a gas containing carbon.

In order to synthesize graphene, a graphene synthesizing apparatus in which an environment of a high temperature is maintained is necessary, and under a high temperature condition, a gas containing carbon is dissociated to form graphene on a surface of a catalyst metal.

### DETAILED DESCRIPTION OF THE INVENTIVE CONCEPT

### Technical Problem

One or more embodiments of the present invention relate to an electric wire structure and a method of manufacturing the electric wire structure.

### Technical Solution

According to an embodiment of the present invention, there is provided an electric wire structure including a copper (Cu) electric wire extending in a direction; and a graphene coating layer formed on an outer portion of the Cu electric wire to surround the Cu electric wire, wherein the Cu electric wire includes Cu having a purity of 99.9% or greater.

### Advantageous Effects

According to the present invention, electric conductivity of an electric wire structure may be improved and noise may be removed.

The effects of the present invention may be deducted from descriptions provided below with reference to accompanying drawings, as well as from the above description.

### DESCRIPTION OF THE DRAWINGS

FIG. 1 is a schematic perspective view of graphene according to the present specification;

FIG. 2 is a perspective view of an electric wire structure according to an embodiment of the present invention;

FIG. 3 is a schematic cross-sectional view of an apparatus of manufacturing an electric wire structure according to an embodiment; and

FIG. 4 is a perspective view of an electric wire structure according to another embodiment of the present invention.

### BEST MODE

According to an aspect of the present invention, there is provided an electric wire structure including a copper (Cu) electric wire extending in a direction; and a graphene coating layer formed on an outer portion of the Cu electric wire to surround the Cu electric wire, wherein the Cu electric wire includes Cu having a purity of 99.9% or greater.

The electric wire structure may further include a metal plated on a surface of the Cu electric wire, wherein the graphene coating layer may be formed on a surface of the metal plated on the surface of the Cu electric wire so as to surround the Cu electric wire.

The metal plated on the surface of the Cu electric wire may be one of gold (Au), silver (Ag), nickel (Ni), and rhodium (Rh).

The graphene coating layer may be formed to surround the Cu electric wire by a rapid-thermal chemical vapor deposition (CVD) process.

The graphene coating layer may be formed on the outside of the Cu electric wire when a gas containing carbon is injected during the rapid-thermal CVD process.

The gas containing carbon may be methane (CH₄) gas.

A size of a crystal of Cu metal forming the Cu electric wire may be greater than a size of a crystal of pure Cu metal.

Crystals of the Cu metal forming the Cu electric wire may be grown in a certain direction.

According to an aspect of the present invention, there is provided a method of manufacturing an electric wire structure, the method including: providing a copper (Cu) electric wire extending in a direction in a chamber; supplying a gas containing carbon into the chamber; increasing a temperature in the chamber to a temperature of 600° C. or greater rapidly within a few seconds to a few minutes, in order to heat the Cu electric wire; and injecting a gas containing carbon into the chamber, wherein the Cu electric wire includes Cu having a purity of 99.9% or greater.

The gas containing carbon may be dissociated to form a graphene coating layer surrounding the Cu electric wire.

The method may further include cooling down the graphene coating layer, after the forming of the graphene coating layer surrounding the Cu electric wire.

The gas containing carbon may be methane (CH₄) gas.

A size of a crystal of Cu metal forming the Cu electric wire may be greater than a size of a crystal of pure Cu metal.

Crystals of the Cu metal forming the Cu electric wire may be grown in a certain direction.

A metal rather than Cu or an alloy may be plated on a surface of the Cu electric wire.

The metal plated on the surface of the Cu electric wire may be one of gold (Au), silver (Ag), nickel (Ni), and rhodium (Rh).

### MODE OF THE INVENTION

As the inventive concept allows for various changes and numerous embodiments, particular embodiments will be illustrated in the drawings and described in detail in the written description. The attached drawings for illustrating one or more embodiments are referred to in order to gain a sufficient understanding, the merits thereof, and the objectives accomplished by the implementation. However, the embodiments may have different forms and should not be construed as being limited to the descriptions set forth herein.

The exemplary embodiments will be described below in more detail with reference to the accompanying drawings. Those components that are the same or are in correspondence are rendered the same reference numeral regardless of the figure number, and redundant explanations are omitted.

While such terms as “first,” “second,” etc., may be used to describe various components, such components must not be limited to the above terms. The above terms are used only to distinguish one component from another.

An expression used in the singular encompasses the expression of the plural, unless it has a clearly different meaning in the context.

In the present specification, it is to be understood that the terms such as “including,” “having,” and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

It will be understood that when a layer, region, or component is referred to as being “formed on” another layer, region, or component, it can be directly or indirectly formed on the other layer, region, or component. That is, for example, intervening layers, regions, or components may be present.

Sizes of components in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

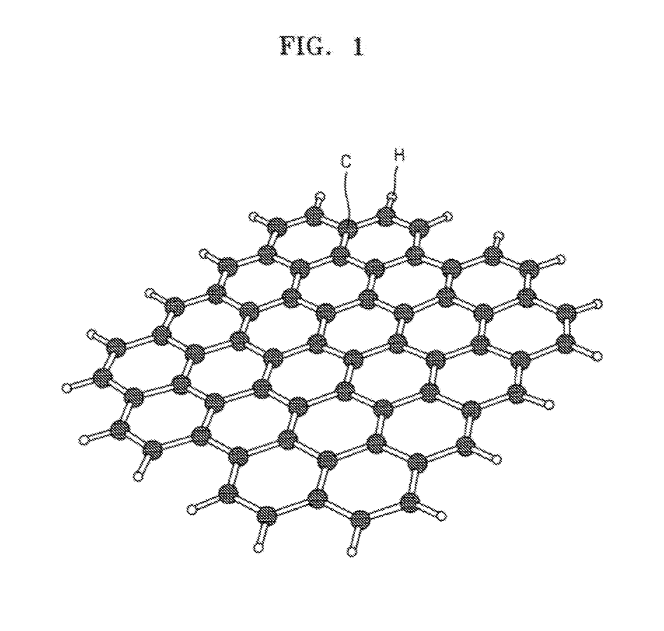

FIG. 1 is a schematic perspective view of graphene according to the present specification.

The term “graphene” used herein denotes a sheet-shaped graphene in which a plurality of carbon atoms are joined together with a multiple covalent bond to for a polycyclic aromatic molecule, and the carbon atoms joined together with a multiple covalent bond have a six-membered ring as a fundamental repeat unit and may further include a five-membered ring and/or a seven-membered ring. Therefore, the graphene layer is a monolayer of carbon atoms (C) forming covalent bonds (typically, sp2 bonding). The graphene layer may have various structures and these structures may depend on a five-membered ring content and/or a seven-membered ring content of graphene.

The graphene layer may be formed of a monolayer of graphene as shown in the drawing, but may be formed of multiple stacked layers. Typically, a side end of the graphene may be saturated with hydrogen atoms (H).

Graphene is a nano-material of a two-dimensional plane structure, and may have various physical, chemical, electrical, and optical characteristics. In particular, graphene may have a charge mobility that is about a hundred times greater than that of silicon (Si) and about a hundred and fifty (150) times greater than that of copper (Cu), and may have an allowable current density that is about a hundred times greater than Cu.

In addition, since graphene is a nano-material having two-dimensional plane structure, graphene may be variously modified to be used.

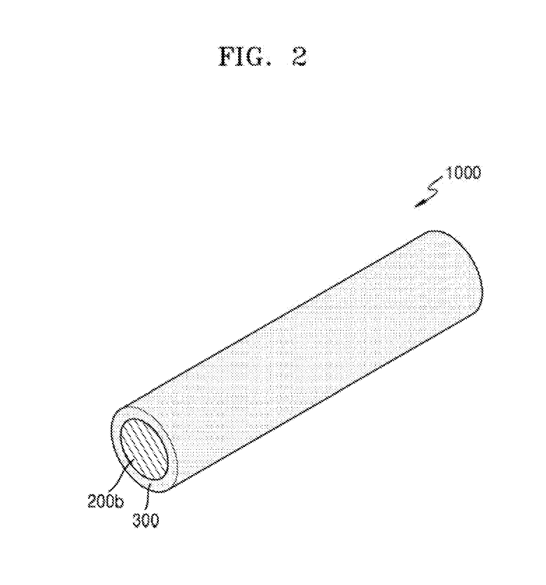

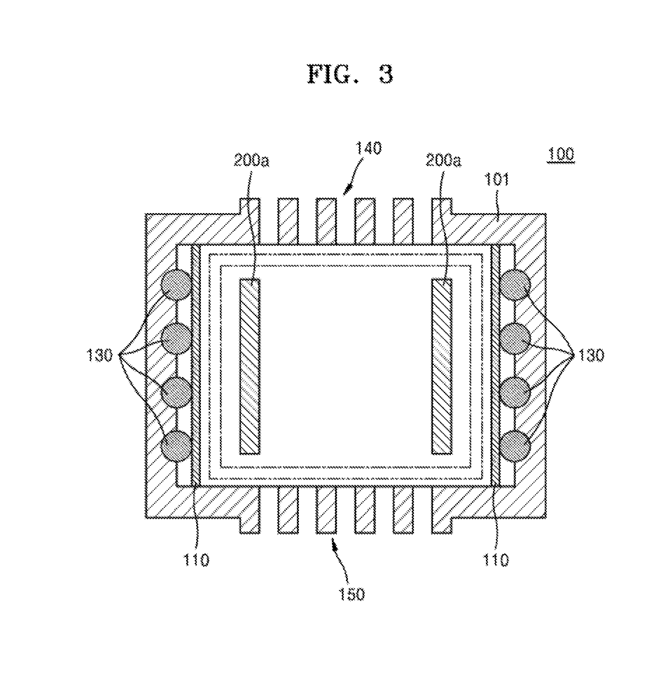

FIG. 2 is a perspective view of an electric wire structure 1000 according to an embodiment of the present invention, and FIG. 3 is a schematic cross-sectional view of an apparatus 100 for manufacturing an electric wire structure for forming the electric wire structure.

The electric wire structure 1000 according to the present embodiment may include a Cu electric wire 200b and a graphene coating layer 300 coated on a surface of the Cu electric wire 200b to surround the Cu electric wire 200b.

As an alternative embodiment, the Cu electric wire 200b may include Cu metal having 99.9% purity or greater.

When the Cu forming the Cu electric wire 200b has low purity and many other atoms, it is difficult to evenly coat the graphene on the surface of the Cu electric wire 200b due to other atoms than the Cu metal during the forming of the electric wire structure 1000.

Accordingly, since the electric wire structure 1000 according to the present embodiment includes the Cu electric wire 200b having Cu metal of 99.9% or greater purity, the graphene may be evenly coated when forming the graphene coating layer 300.

The charge mobility of graphene is about a hundred times greater than Si and about a hundred and fifty (150) times greater than Cu, as described above. Moreover, graphene has an allowable current density that is about a hundred times greater than that of Cu, and has high thermal conductivity.

Therefore, the electric wire structure 1000 according to the present embodiment, in which the graphene coating layer 300 is formed to surround the Cu electric wire 200b, may have excellent electrical characteristics such as charge mobility, current density, thermal conductivity, etc.

Also, when an electric current of radio frequency (high pitch) flows in the electric wire, a skin effect may occur, that is, the electric current may not flow throughout entire cross-section of the electric wire, but may concentrate around the surface of the electric wire.

However, in the electric wire structure 1000 according to the present embodiment, the graphene coating layer 300 having excellent charge mobility is formed on the surface of the Cu electric wire 200b so as to surround the Cu electric wire 200b, and thus, the electric current concentrated around the surface of the electric wire may be rapidly moved to improve electric conductivity, and moreover, noise may be removed.

Hereinafter, a method of manufacturing the electric wire structure 1000 according to the present embodiment by using an electric wire structure manufacturing apparatus 100 will be described below in detail.

In order to manufacture the electric wire structure 1000 according to the present embodiment, the Cu electric wire 200a extending in a direction shown in FIG. 3 has to be included in the electric wire structure manufacturing apparatus 100.

The electric wire structure according to the present invention aims to form an electric wire having excellent electric conductivity and getting rid of noise, and thus, the Cu electric wire 200a having a wire shape that is long in a direction may be included in the electric wire structure manufacturing apparatus 100.

In the drawings, two Cu electric wires 200a are included in the electric wire structure manufacturing apparatus 100, but the present invention is not limited thereto, that is, only one Cu electric wire 200a may be included or three or more Cu electric wires 200a may be included in the electric wire structure manufacturing apparatus 100.

Referring to FIG. 3, the electric wire structure manufacturing apparatus 100 may include a chamber 101, lamp portions 130, and conductive plates 110. In addition, the electric wire structure manufacturing apparatus 100 may further include a gas supply 140, a discharge portion 150, a decompressor (not shown), and a gate (not shown).

FIG. 3 shows a cross-section of the electric wire structure manufacturing apparatus 100, and according to the present embodiment, the chamber 101 is a hexagon having a square cross-section. However, the shape of the chamber 101 is not limited thereto, for example, the chamber 101 may be formed as other polygons than the hexagon, a polyprism, a polypyramid, or a sphere.

The lamp portions 130 may be respectively formed on surfaces facing the Cu electric wires 200a in order to maximize an area of radiation heat applied to the Cu electric wires 200a, but are not limited thereto. For example, the lamp portions 130 may be respectively disposed on three or more surfaces of the chamber 101, or may be disposed only one surface of the chamber 101.

The lamp portions 130 may include halogen lamps, and a plurality of halogen lamps may be arranged with predetermined intervals therebetween. The halogen lamps may emit near-infrared rays, mid-infrared rays, and/or visible rays.

The lamp portions 130 may further include a window (not shown), and the window may be arranged to surround outer circumferences of the halogen lamps or may be arranged at one sides of the halogen lamps that are arranged in parallel in a direction. The window may include a transparent material, e.g., quartz. The window may protect the halogen lamps, and may improve optical efficiency.

However, since the Cu electric wire 200a according to the present embodiment has high reflectivity, the Cu electric wire 200a may mostly reflect the radiation heat supplied from the lamp portions 130. In this case, the Cu electric wire 200a is not easily heated, and it may take a long time period to reach a temperature at which the graphene coating layer 300 is formed.

Therefore, the electric wire structure manufacturing apparatus 100 may further include the conductive plates 110 as an alternative example.

The conductive plates 110 convert the radiation heat from the lamp portions 30 to convection heat and discharge the convection heat into the chamber 101, so as to heat the Cu electric wires 200a and a gas. A temperature of the conductive plates 110 may rise due to the radiation heat discharged from the lamp portions 130. The conductive plates 110 may include any type of material, a temperature of which may rise due to the radiation heat.

As an embodiment, the conductive plates 110 may include graphite or metal coated with an oxidation layer. When an oxidation layer is coated on metal, the reflectivity may be reduced and absorption rate of the radiation heat may increase.

The conductive plates 110 may be arranged to face the Cu electric wires 200a, together with the lamp portions 130.

That is, the conductive plates 110 may be formed in parallel with the lamp portions 130, as shown in FIG. 3, and may be disposed between the lamp portions 130 and the Cu electric wires 200a to convert the radiation heat from the lamp portions 130 into the convection heat to heat the Cu electric wires 200a.

As shown in FIG. 3, the conductive plates 110 may be arranged on opposite surfaces of the chamber 101 with the Cu electric wires 200a therebetween, like the lamp portions 130. However, the present invention is not limited thereto, that is, only one conductive plate 110 may be formed in the chamber 101 as another embodiment.

As described above, the conductive plates 110 discharge the convection heat to heat the Cu electric wires 200a and the gas, so that the temperature inside the chamber 101 may be changed to a high temperature that is optimal for synthesizing graphene.

In addition, since the conductive plates 110 are provided, the heat generated in the chamber 101 may be locked in to maintain the high temperature in the chamber 101.

The electric wire structure manufacturing apparatus 100 according to the present embodiment may increase the temperature in the chamber 101 to the high temperature of 600° C. within a few seconds to a few minutes by using the conductive plates 110 and the lamp portions 130.

As an alternative embodiment, the temperature in the chamber 101 may rapidly rise to the high temperature of 900 to 1050° C.

That is, the electric wire structure 1000 according to the present embodiment may be formed by depositing the graphene coating layer 300 on the surface of the Cu electric wire 200b that is heated, by a rapid-thermal CVD method.

That is, the electric wire structure manufacturing apparatus 100 according to the present embodiment may rapidly rise the temperature in the chamber 101 to make a high temperature condition in which the graphene coating layer 300 may be formed.

Since the temperature in the chamber 101 may rapidly rise to the high temperature condition due to the radiation heat discharged from the lamp portions 130 and the convection heat transferred via the conductive plates 110, the Cu electric wires 200a included in the chamber 101 are recrystallized.

That is, crystal grains of the Cu metal forming the Cu electric wires 200a may increase a lot at a rapid temperature rising speed of a few seconds to a few minutes. Moreover, the crystal grains of the Cu metal forming the Cu electric wires 200a may be grown in a certain direction.

Accordingly, the crystal grains of the recrystallized Cu metal forming the Cu electric wire 200b (see FIG. 2) after being rapidly heated are greater than those of pure Cu metal before recrystallization and are grown in a certain direction, and thus, the electric current may be transferred sufficiently.

That is, the Cu electric wire 200b (see FIG. 2) including the recrystallized Cu metal may have higher electric conductivity and less resistance and noise than those of the Cu electric wire 200a including the pure Cu metal before the recrystallization.

Moreover, since the crystal grains of the recrystallized Cu metal increase, the graphene may be evenly synthesized when the graphene coating layer 300 is formed, and accordingly, surface resistance may be reduced.

Hereinafter, the Cu electric wire 200a including the pure Cu metal before being heated will be described with reference to FIG. 3, and the Cu electric wire 200b including the recrystallized Cu metal after being heated will be described with reference to FIG. 2 for convenience of description.

The gas supply 140 may include a plurality of nozzles, and may supply a gas including carbon into the chamber 101.

The gas containing carbon is a reaction gas for forming graphene, and as an alternative embodiment, methane (CH₄) may be used.

The gas containing carbon is not limited thereto, that is, one or more selected from the group consisting of carbon monoxide (CO), ethane (C₂H₆), ethylene (CH₂), ethanol (C₂H₅), acetylene (C₂H₂), propane (CH₃CH₂CH₃), propylene (C₃H₆), butane (C₄H₁₀), pentane (CH₃(CH₂)₃CH₃), pentene (C₅H₁₀), cyclopentadiene (C₅H₆), hexane (C₆H₁₄), cyclohexane (C₆H₁₂), benzene (C₆H₆), toluene (C₇H₈), etc. may be used.

The gas containing carbon is separated into carbon atoms and hydrogen atoms at a high temperature. The carbon atoms included in the gas containing carbon may be deposited on the heated Cu electric wire 200b by the rapid-thermal CVD method, so that the graphene coating layer 300 may be formed to surround the Cu electric wire 200b.

The Cu electric wire 200b that is rapidly heated is recrystallized as described above, and thus, electric conductivity may be improved and noise may be reduced while the electric current moves.

In a case where the graphene coating layer 300 having the excellent electric conductivity is formed on the surface of the Cu electric wire 200b to surround the Cu electric wire 200b, the above effect may be maximized.

That is, even when the graphene is formed on the surface of pure Cu electric wire to surround the electric wire, the electric conductivity of the graphene itself is excellent, and thus, electric conductivity may be improved and noise may be removed.

In addition, in the electric wire structure 1000 according to the embodiment, the Cu electric wire 200b is also rapidly heated, and thus, electric conductivity is improved. Moreover, since the graphene coating layer 300 is formed to surround the Cu electric wire 200b, the effect of increasing the electric conductivity and removing the noise may be maximized.

Also, the crystal grains of the recrystallized Cu metal increase, the graphene having a very low resistance value may be formed to evenly surround the Cu electric wire 200b.

As alternative embodiment, since the Cu electric wire 200a including the Cu metal having a purity of 99.9% or greater is used, there may be rarely other atoms than the Cu atoms even when the temperature in the chamber 101 rapidly rises, and thus, the graphene may be evenly synthesized on the surface of the Cu electric wire 200b.

In addition, the gas supply 140 may supply an ambient gas, as well as the gas containing carbon, into the chamber 101. The ambient gas may include an inert gas such as helium or argon, and a nonreaction gas such as hydrogen for maintaining the surface of the Cu electric wire 200a clean.

In the present embodiment, a case where one gas supply 140 supplies both the gas containing carbon and the ambient gas is described, but the present invention is not limited thereto. For example, a gas supply for supplying the gas containing carbon and a gas supply for supplying the ambient gas may be separately provided to respectively supply the gas containing carbon and the ambient gas into the chamber 101.

The discharge portion 150 may exhaust the gas that remained after being used to form the graphene coating layer 300 in the chamber 101.

The discharge portion 150 may be disposed in a surface facing the gas supply 140 in order to maximize the discharging effect. However, the present invention is not limited to the above example, and the arrangement structure and the number of discharge portions 150 may be variously implemented.

Hereinafter, processes of synthesizing graphene on the surface of the heated Cu electric wire 200b and forming the graphene coating layer 300 so as to surround the Cu electric wire 200b will be described in detail below.

First, one, two, or more Cu electric wires 200a are arranged in the chamber 101, and after that, the gas included in the chamber 101 is externally discharged by using a vacuum pump (not shown) via the decompressor (not shown). The pressure of the inside the chamber 101 may be less than atmospheric pressure, e.g., hundreds of torr to 10⁻⁶ torr.

As an alternative embodiment, the Cu electric wire 200a may be disposed to face the conductive plates 110.

After that, the ambient gas, e.g., the inert gas such as helium and argon and/or the nonreaction gas such as hydrogen for maintaining the surface of the Cu electric wire 200a clean.

After injecting the ambient gas, the Cu electric wire 200a and the conductive plates 110 may be heated by the lamp portions 130.

When the temperature of the conductive plates 110 and the Cu electric wire 200b sufficiently increases due to the radiation heat discharged from the lamp portions 130, the temperature in the chamber 101 may be high enough to synthesize graphene due to the heat dissipated from the Cu electric wires 200a and the conductive plates 110.

As an alternative embodiment, a high temperature environment of 600° C. or greater may be generated in the chamber 101, and as another alternative embodiment, the internal portion of the chamber 101 may maintain the high temperature of 900 to 1050° C.

Accordingly, recrystallization, that is, sizes of the crystal grains and orientation of the crystal grains of the Cu metal are changed in the Cu electric wire 200b that is heated because the temperature inside the chamber 101 rises to the temperature that is high enough to synthesize graphene due to the lamp portions 130 and the conductive plates 110 within a short time period of a few seconds to a few minutes.

After that, the gas containing carbon, that is, a reaction gas, is supplied through the gas supply 140.

As an alternative embodiment, methane (CH₄) gas may be supplied as the gas containing carbon.

Here, the discharge portion 150 is also disposed at a side facing the gas supply 140, and thus, the reaction gas may efficiently flow through the chamber 101 by supplying the reaction gas through the gas supply 140 at a side while exhausting the gas via the discharge portion 150 at the other side.

The reaction gas containing carbon may receive energy in the chamber 101 to be decomposed to be used in synthesizing the graphene.

As an alternative embodiment, when CH₄ gas is used as the reaction gas, the methane gas is dissociated into C and H in the chamber 101.

When the reaction gas passes through the chamber 101, in which the high temperature environment is generated, the reaction gas contacts the Cu electric wire 200b, that is, the surface of the Cu electric wire 200b, and during this process, the decomposed reaction gas is absorbed by the Cu electric wire 200b, the surface of which is activated, to grow graphene crystals.

That is, as the graphene crystals are grown, the graphene coating layer 300 having a constant thickness may be formed to surround the surface of the Cu electric wire 200b.

As an alternative embodiment, the graphene coating layer 300 may be formed on the surface of the Cu electric wire 200b by the rapid-thermal CVD method because the temperature in the chamber 101 rapidly rises enough to synthesize the graphene within a short time period of a few seconds to a few minutes, as described above.

In the present embodiment, the method of supplying the gas containing carbon after heating the Cu electric wire 200a by using the lamp portions 130 is described as above, but the present invention is not limited thereto.

That is, before discharging the radiation heat from the lamp portions 130, on discharging the radiation heat from the lamp portions 130, or after discharging the radiation heat, the gas containing carbon may be supplied. That is, the lamp portions 130 may operate before supplying the gas containing carbon, while supplying the gas containing carbon, or after supplying the gas containing carbon.

In a case where the radiation heat irradiated from the lamp portions 130 is the light of the near-infrared ray wavelength band, the Cu electric wire 200a and the conductive plates 110 are heated by the radiation heat, and the inside of the chamber 101 is heated and the gas containing carbon is decomposed by the heat discharged from the heated Cu electric wire 200b and the conductive plates 110. However, the present invention is not limited thereto.

As another embodiment, the lamp portions 130 may emit light of the mid-infrared and/or visible light wavelength band, as well as the near-infrared ray wavelength band. In this case, the light of the near-infrared wavelength band emitted from the lamp portions 130 supplies energy to the Cu electric wire 200a and the conductive plates 110, and the inside of the chamber 101 may be heated by the Cu electric wire 200b and the conductive plates 110.

At the same time, the light of the mid-infrared and/or visible ray wavelength band emitted from the lamp portions 130 may heat the gas containing carbon, wherein the gas is supplied into the chamber 101.

In other words, the gas containing carbon may receive energy from the heat in the chamber 101 that is rapidly heated by the lamp portions 130 and the conductive plate 110, and the light of the mid-infrared and/or visible ray wavelength bands, so as to be decomposed. Therefore, synthesizing of graphene in the chamber 101 may be actively performed within a short period of time.

After synthesizing graphene on the surface of the Cu electric wire 200b in the chamber 101 of a high temperature, the electric wire structure 1000 in which the graphene coating layer 300 is formed is cooled down to stabilize the graphene coating layer 300.

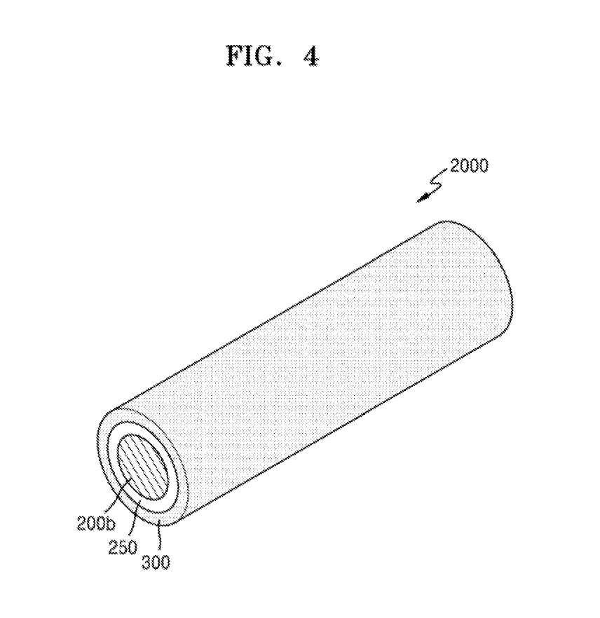

FIG. 4 is a schematic perspective view of an electric wire structure 2000 according to another embodiment of the present invention. In FIG. 4, like reference numerals as those of FIG. 2 denote the same elements, and detailed descriptions thereof are omitted.

The electric wire structure 2000 according to the present embodiment may include the Cu electric wire 200b extending in a direction, a metal 250 plated on the surface of the Cu electric wire 200b, and the graphene coating layer 300 surrounding the Cu electric wire 200b and the metal 250.

The Cu electric wire 200b may extend in a direction as a wire shape.

As an alternative embodiment, the Cu electric wire 200b may include Cu metal having 99.9% purity or greater.

When the Cu forming the Cu electric wire 200b has low purity and many other atoms, it is difficult to evenly coat the graphene on the surface of the Cu electric wire 200b due to other atoms than the Cu metal during the forming of the electric wire structure 2000.

Accordingly, since the electric wire structure 2000 according to the present embodiment includes the Cu electric wire 200b having Cu metal of 99.9% or greater purity, the graphene may be evenly coated on the surface of the Cu electric wire.

Metal or alloy may be plated on the surface of the Cu electric wire 200b.

The metal 250 may include at least one metal or alloy from nickel (Ni), cobalt (Co), iron (Fe), platinum (Pt), gold (Au), silver (Ag), aluminum (Al), chrome (Cr), magnesium (Mg), manganese (Mn), molybdenum (Mo), rhodium (Rh), silicon (Si), tantalum (Ta), titanium (Ti), tungsten (W), uranium (U), vanadium (V), palladium (Pd), yttrium (Y), zirconium (Zr), germanium (Ge), brass, bronze, white brass, and stainless steel, but is not limited thereto, and any metal or alloy having high electric conductivity may be plated.

As shown in FIG. 4, the electric wire structure 2000 according to the present embodiment may include the graphene coating layer 300 surrounding a surface of the metal 250 plated on the Cu electric wire 200b.

That is, the graphene coating layer 300 may be formed to a constant thickness on the surface of the metal 250 that is plated on the Cu electric wire 200b to surround an exterior of the Cu electric wire 200b.

In the electric wire structure 2000 according to the present embodiment, the Cu electric wire 200a on which the metal 250 is plated may be disposed in the electric wire structure manufacturing apparatus 100.

Next, the gas in the chamber 101 may be externally discharged via the decompressor (not shown) by using a vacuum pump (not shown). The pressure of the inside of the chamber 101 may be less than the atmospheric pressure, e.g., hundreds of torr to 10⁻⁶ torr.

After that, the ambient gas, e.g., the inert gas such as helium and argon and/or the nonreaction gas such as hydrogen for maintaining the surface of the Cu electric wire 200a clean.

After injecting the ambient gas, the Cu electric wire 200a on which the metal 250 is coated and the conductive plates 110 may be heated by the lamp portions 130.

When the temperature of the conductive plates 110 and the Cu electric wire 200b sufficiently increases due to the radiation heat discharged from the lamp portions 130, the temperature in the chamber 101 may be high enough to synthesize graphene due to the heat dissipated from the Cu electric wires 200b and the conductive plates 110.

As an alternative embodiment, a high temperature environment of 600° C. or greater may be generated in the chamber 101, and as another alternative embodiment, the internal portion of the chamber 101 may maintain the high temperature of 900 to 1050° C.

Accordingly, recrystallization, that is, sizes of the crystal grains and orientation of the crystal grains of the Cu metal are changed in the Cu electric wire 200a that is heated because the temperature inside the chamber 101 rises to the temperature that is high enough to synthesize graphene due to the lamp portions 130 and the conductive plates 110 within a short time period of a few seconds to a few minutes.

After that, the gas containing carbon, that is, a reaction gas, is supplied through the gas supply 140.

As an alternative embodiment, CH₄ gas may be supplied as the gas containing carbon.

The reaction gas containing carbon may receive energy in the chamber 101 to be decomposed to be used in synthesizing the graphene.

As an alternative embodiment, when CH₄ gas is used as the reaction gas, the CH₄ gas is dissociated into C and H in the chamber 101.

When the reaction gas passes through the chamber 101, in which the high temperature environment is provided, the reaction gas contacts the Cu electric wire 200b plated with the metal 250, that is, the surface of the metal 250 coated on the surface of the Cu electric wire 200b, and in this process, the decomposed reaction gas is absorbed by the metal 250, the surface of which is activated, to grow graphene crystals.

That is, as the graphene crystals grow on the surface of the metal 250 coated on the Cu electric wire, the graphene coating layer 300 having a constant thickness may be formed to surround the Cu electric wire 200b and the metal 250.

That is, in the electric wire structure 2000 according to the present embodiment, the graphene coating layer 300 may be formed on the surface of the metal 250 plated on the Cu electric wire 200b so as to surround the Cu electric wire 200b.

As an alternative embodiment, the graphene coating layer 300 may be formed on the surface of the plated metal 250 by the rapid-thermal CVD method because the temperature in the chamber 101 rapidly rises enough to synthesize the graphene within a short time period of a few seconds to a few minutes, as described above.

In the present embodiment, the method of supplying the gas containing carbon after heating the Cu electric wire 200a by using the lamp portions 130 is described as above, but the present invention is not limited thereto.

After synthesizing graphene on the surface of the metal 250 plated to surround the Cu electric wire 200b in the chamber 101 of a high temperature, the electric wire structure 2000 in which the graphene coating layer 300 is formed may be cooled down to stabilize the graphene coating layer 300.

Although a few embodiments of the present invention have been shown and described, it would be appreciated by those skilled in the art that changes may be made in these embodiments without departing from the principles and spirit of the invention, the scope of which is defined in the claims and their equivalents.

1. An electric wire structure comprising:
a copper (Cu) electric wire extending in a direction; and
a graphene coating layer formed on an outer portion of the Cu electric wire to surround the Cu electric wire,
wherein the Cu electric wire includes Cu having a purity of 99.9% or greater.

2. The electric wire structure of claim 1, further comprising
a metal plated on a surface of the Cu electric wire,
wherein the graphene coating layer is formed on a surface of the metal plated on the surface of the Cu electric wire so as to surround the Cu electric wire.

3. The electric wire structure of claim 2, wherein the metal plated on the surface of the Cu electric wire is one of gold (Au), silver (Ag), nickel (Ni), and rhodium (Rh).

4. The electric wire structure of claim 1, wherein the graphene coating layer is formed to surround the Cu electric wire by a rapid-thermal chemical vapor deposition (CVD) process.

5. The electric wire structure of claim 4, wherein the graphene coating layer is formed on the outside of the Cu electric wire when a gas containing carbon is injected during the rapid-thermal CVD process.

6. The electric wire structure of claim 5, wherein the gas containing carbon is methane (CH₄) gas.

7. The electric wire structure of claim 1, wherein a size of a crystal of Cu metal forming the Cu electric wire is greater than a size of a crystal of pure Cu metal.

8. The electric wire structure of claim 1, wherein crystals of the Cu metal forming the Cu electric wire are grown in a certain direction.

9. A method of manufacturing an electric wire structure, the method comprising:
providing a copper (Cu) electric wire extending in a direction in a chamber;
supplying a gas containing carbon into the chamber;
increasing a temperature in the chamber to a temperature of 600° C. or greater rapidly within a few seconds to a few minutes, in order to heat the Cu electric wire; and
injecting a gas containing carbon into the chamber,
wherein the Cu electric wire includes Cu having a purity of 99.9% or greater.

10. The method of claim 9, wherein the gas containing carbon is dissociated to form a graphene coating layer surrounding the Cu electric wire.

11. The method of claim 10, further comprising cooling down the graphene coating layer, after the forming of the graphene coating layer surrounding the Cu electric wire.

12. The method of claim 9, wherein the gas containing carbon is methane (CH₄) gas.

13. The method of claim 9, wherein a size of a crystal of Cu metal forming the Cu electric wire is greater than a size of a crystal of pure Cu metal.

14. The method of claim 9, wherein crystals of the Cu metal forming the Cu electric wire are grown in a certain direction.

15. The method of claim 9, wherein a metal rather than Cu or an alloy is plated on a surface of the Cu electric wire.

16. The method of claim 15, wherein the metal plated on the surface of the Cu electric wire is one of gold (Au), silver (Ag), nickel (Ni), and rhodium (Rh).
